(19) United States
(12) Patent Application Publication
(10) Pub. No.: US 2026/0063995 A1
(43) Pub. Date: Mar. 5, 2026

(54) SEMICONDUCTOR PHOTORESIST COMPOSITIONS AND METHODS OF FORMING PATTERNS USING THE COMPOSITIONS

(71) Applicant: SAMSUNG SDI CO., LTD., Yongin-si (KR)

(72) Inventors: Chungheon LEE, Suwon-si (KR); Minyoung LEE, Suwon-si (KR); Jihyun YOON, Suwon-si (KR); Yaeun SEO, Suwon-si (KR); Seongyeon HWANG, Suwon-si (KR); Taegeun SEONG, Suwon-si (KR); Minhye KIM, Suwon-si (KR)

(21) Appl. No.: 19/265,818

(22) Filed: Jul. 10, 2025

(30) Foreign Application Priority Data
Aug. 27, 2024 (KR) 10-2024-0115270

(51) Int. Cl. G03F 7/004; G03F 7/00; H01L 21/311; H01L 21/3213

(52) U.S. Cl. CPC G03F 7/0048; G03F 7/0042; G03F 7/70033

(57) ABSTRACT

A semiconductor photoresist composition includes an organometallic compound; an organic solvent including a ketone-based solvent; and an organic acid compound. A method of forming patterns using the same is disclosed.

### CROSS-REFERENCE TO RELATED APPLICATION

The present application claims priority to and the benefit of Korean Patent Application No. 10-2024-0115270, filed in the Korean Intellectual Property Office on Aug. 27, 2024, the entire content of which is incorporated herein by reference.

### BACKGROUND

### 1. Field

This disclosure relates to semiconductor photoresist compositions and methods of forming patterns using the same.

### 2. Description of the Related Art

Extreme ultraviolet (EUV) lithography has gained attention as an important (e.g., essential or desired) technology for manufacturing a next generation semiconductor device. EUV lithography is a pattern-forming technology that uses an EUV ray with a wavelength of 13.5 nm as an exposure light source. In EUV lithography, extremely fine patterns (e.g., less than or equal to 20 nm) may be formed through an exposure process during the manufacturing of semiconductor devices.

The realization of extreme ultraviolet (EUV) lithography depends on development of compatible photoresists that can achieve a spatial resolution of less than or equal to 16 nm. Currently, efforts are underway to address the limitations of chemically amplified (CA) photoresists, such as in resolution, photospeed, and/or feature roughness (also referred to as a line edge roughness or LER), to meet the specifications for the next generation device.

Intrinsic image blurring due to an acid-catalyzed reaction in these polymer-type (kind) photoresists limits a resolution in small feature sizes, a phenomenon known in electron beam (e-beam) lithography for a long time. The chemically amplified (CA) photoresists are designed for high sensitivity, but their typical elemental makeup reduce light absorbance of the photoresists at a wavelength of 13.5 nm and thus decrease their sensitivity, which makes it more difficult to use the chemically amplified (CA) photoresists under an EUV exposure.

Additionally, the CA photoresists may have difficulties with small feature sizes due to roughness issues. Experimental results show that line edge roughness (LER) of the CA photoresists increases as photospeed decreases, partially due to inherent characteristics of acid catalyst processes. Accordingly, a novel high-performance photoresist is desired (e.g., required) in the semiconductor industry to address these defects and problems of the CA photoresists.

To overcome the drawbacks of the chemically amplified (CA) organic photosensitive composition, research has been conducted on inorganic photosensitive compositions. The inorganic photosensitive compositions are mainly used for negative tone patterning and have resistance against removal by a developer composition due to chemical modification through a non-chemical amplification mechanism. The inorganic compositions contain an inorganic element with a higher EUV absorption rate than hydrocarbons, and thus may secure or ensure suitable sensitivity through the nonchemical amplification mechanism. In addition, the inorganic compositions are less sensitive to stochastic effects and thus may have low line edge roughness and fewer defects.

Inorganic photoresists based on peroxopolyacids of tungsten mixed with tungsten, niobium, titanium, and/or tantalum have been reported as radiation sensitive materials for patterning (see also, U.S. Pat. No. 5,061,599; and H. Okamoto, T. Iwayanagi, K. Mochiji, H. Umezaki, T. Kudo, Applied Physics Letters, 49 (5), 298-300, 1986, the entire content of each of which is incorporated herein by reference).

These materials are effective for patterning large pitches for bilayer configuration as far ultraviolet (deep UV), X-ray, and electron beam sources. More recently, cationic hafnium metal oxide sulfate (HfSOx) materials along with a peroxo complexing agent has been used to image a 15 nm half-pitch (HP) through projection EUV exposure, and impressive performance has been obtained (see also, US 2011-0045406; and J. K. Stowers, A. Telecky, M. Kocsis, B. L. Clark, D. A. Keszler, A. Grenville, C. N. Anderson, P. P. Naulleau, Proc. SPIE, 7969, 796915, 2011, the entire content of each of which is incorporated herein by reference). This system exhibits better performance as a non-CA photoresist and has a practicable photospeed close to the requirement for an EUV photoresist. However, the hafnium metal oxide sulfate material having the peroxo complexing agent has a few practical drawbacks. First, these materials are coated in a mixture of corrosive sulfuric acid/hydrogen peroxide and may have insufficient shelf-life stability. Second, as a composite mixture, a structural change thereof for performance improvement is not easy. Third, development has to be performed in a tetramethylammonium hydroxide (TMAH) solution at a high (e.g., extremely high) concentration of 25 wt % and/or the like.

Recently, active research has been conducted on molecules (e.g., materials) containing tin, which have excellent or suitable absorption of extreme ultraviolet rays. Among these, organotin polymers dissociate alkyl ligands by light absorption or secondary electrons, crosslinking with adjacent chains through oxo bonds to enable negative tone patterning that resists removal by an organic developer. This organotin polymer exhibits greatly improved sensitivity while maintaining suitable resolution and line edge roughness, but the patterning characteristics need further improvement for commercial applications.

### SUMMARY

An aspect according to some embodiments is directed toward a semiconductor photoresist composition with (having) enhanced (e.g., improved) sensitivity and exposure delay characteristics.

An aspect according to some embodiments is directed toward a method of forming patterns using the semiconductor photoresist composition.

Additional aspects will be set forth in part in the description which follows and, in part, will be apparent from the description, or may be learned by practice of the presented embodiments of the disclosure.

A semiconductor photoresist composition according to some embodiments of includes an organometallic compound, an organic solvent including a ketone-based solvent, and an organic acid compound.

A method of forming patterns according to some embodiments includes forming an etching-objective layer on a substrate, coating the semiconductor photoresist composition on the etching-objective layer to form a photoresist layer, patterning the photoresist layer to form a photoresist pattern and etching the etching-objective layer using the photoresist pattern as an etching mask.

The semiconductor photoresist composition according to some embodiments can improve surface roughness by enhancing coating properties and provide a photoresist pattern with improved moisture and heat stability. For example, the semiconductor photoresist composition can improved surface roughness by enhancing the coating properties of the photoresist layer. This enhancement leads to the formation of a photoresist pattern with superior moisture and heat stability, which maintain the integrity of the patterns during subsequent processing steps (e.g., acts or tasks). Improved moisture and heat stability ensure that the photoresist pattern remains intact and precise, even under challenging environmental conditions, thereby contributing to the overall reliability and performance of the semiconductor devices.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIGS. 1A-1E are cross-sectional views for explaining a method of forming patterns using a semiconductor photoresist composition according to some example embodiments.

### DETAILED DESCRIPTION

Hereinafter, referring to the drawings, embodiments are described in more detail. In the following description of the present disclosure, the functions or constructions known in the related art will not be described in order to clarify the present disclosure.

Throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto. In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element such as a layer, film, region, or substrate is referred to as being “on” another element, it can be directly on the other element or intervening elements may also be present.

As used herein, the term “substituted” refers to replacement of a hydrogen atom by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. The term “unsubstituted” refers to non-replacement of a hydrogen atom by another substituent and remaining as the hydrogen atom.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but the present disclosure is not limited thereto.

As used herein, the term “aryl group” refers to a cyclic substituent in which all atoms in the cyclic substituent have a p-orbital and these p-orbitals are conjugated and may include a monocyclic or fused ring polycyclic (i.e., rings sharing adjacent pairs of carbon atoms) functional group.

As used herein, the term “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

A semiconductor photoresist composition according to some example embodiments is described.

The semiconductor photoresist composition according to some example embodiments includes an organometallic compound, an organic solvent including a ketone-based solvent, and an organic acid compound.

The organic solvent included in the semiconductor photoresist composition according to embodiments of the present disclosure includes a ketone-based solvent, and can induce a crosslinking bond (e.g., facilitate the formation of a crosslinked structure) and entanglement by forming coordination bonds with a number of organometallic compounds through unshared electron pairs of oxygen atoms included in the ketone functional group.

Accordingly, it is desirable or advantageous to use the organic solvent not only for increasing the adsorption to the substrate but also for forming an amorphous thin film.

In addition, because the crosslinking bond and entanglement can compensate for the lack of coordination number, stability against moisture and/or oxygen is improved, so that precipitation due to hydration is prevented or reduced even during long-term storage, and deformation or degradation due to air can be prevented or reduced even if (e.g., when) left alone after coating. That is, both the stability of the semiconductor photoresist composition during long-term storage and the stability of the film formed by the coating the semiconductor photoresist composition may be improved due to the ketone-based solvent.

The ketone-based solvent may have a chain (e.g., linear) structure or a ring (e.g., cyclic) structure, and may be represented, for example, by Chemical Formula 1 or Chemical Formula 2.

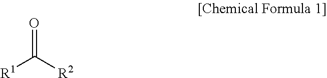

In Chemical Formula 1,

R¹ and R² may each independently be a substituted or unsubstituted C1 to C10 alkyl group;

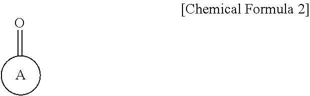

In Chemical Formula 2,

Ring A may be a substituted or unsubstituted C3 to C10 cycloalkyl group.

For example, the ketone-based solvent may be represented by a chain structure of Chemical Formula 1.

For example, the ketone-based solvent represented by Chemical Formula 1 may be represented by any one of Chemical Formula 1-1 to Chemical Formula 1-4.

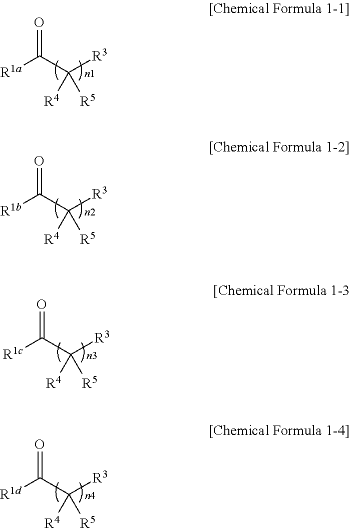

In Chemical Formula 1-1 to Chemical Formula 1-4,
R^{1a} may be a substituted or unsubstituted methyl group,
R^{1b} may be a substituted or unsubstituted ethyl group,
R^{1c} may be a substituted or unsubstituted propyl group,
R^{1d} may be a substituted or unsubstituted butyl group,
R³ may be a substituted or unsubstituted methyl group,
n1 may be one of integers 1 to 7,
n2 may be one of the integers 1 to 6,
n3 may be one of integers 1 to 5,
n4 may be one of integers 1 to 4, and
R⁴ and R⁵ may each independently be hydrogen, halogen, a substituted or unsubstituted C1 to C5 alkyl group, a substituted or unsubstituted C3 to C10 cycloalkyl group, a substituted or unsubstituted C6 to C12 aryl group, and/or a (e.g., any suitable) combination thereof.

In some embodiments, n1 may be one of the integers 1 to 5, n2 may be one of the integers 1 to 4, n3 may be one of the integers 1 to 3, and n4 may be 1 or 2.

In some embodiments, the ketone-based solvent represented by Chemical Formula 1 may be represented by any one of Chemical Formula 1-1 to Chemical Formula 1-3,

n1 may be one of the integers of 1 to 3, n2 may be one of the integers of 1 to 2, and n3 may be 1.

In some embodiments, the ketone-based solvent represented by Chemical Formula 1 may be represented by Chemical Formula 1-1 or Chemical Formula 1-2, n1 may be 1 or 2, and n2 may be 1.

In some embodiments, the number of carbon atoms linked to the ketone functional group in Chemical Formula 1 may be about 4 to about 10. In this case, the ketone-based solvent represented by Chemical Formula 1 may be, for example, pentanone, hexanone, heptanone, octanone, nonanone, decanone, untecanone, and/or the like.

In some embodiments, the number of carbon atoms linked to the ketone functional group in Chemical Formula 1 may be 4 to 8. In this case, the ketone-based solvent represented by Chemical Formula 1 may be, for example, pentanone, hexanone, heptanone, octanone, nonanone, and/or the like.

In some embodiments, the number of carbon atoms linked to the ketone functional group in Chemical Formula 1 may be 4 to 6. In this case, the ketone-based solvent represented by Chemical Formula 1 may be, for example, pentanone, hexanone, heptanone, and/or the like.

In some embodiments, the number of carbon atoms linked to the ketone functional group in Chemical Formula 1 may be 4 or 5. In this case, the ketone-based solvent represented by Chemical Formula 1 may be, for example, pentanone, hexanone, and/or the like.

In some embodiments, the ketone-based solvent represented by Chemical Formula 1 may be pentanone.

The organic solvent including the ketone-based solvent may further include an acetate-based solvent.

If the acetate-based solvent is further included, coating uniformity and coating thickness stability can be improved.

The ketone-based solvent and the acetate-based solvent may be included in a weight ratio of about 99:1 to about 50:50.

In some embodiments, the ketone-based solvent and the acetate-based solvent may be included in a weight ratio of about 99:1 to about 80:20 or a weight ratio of about 90:10 to about 70:30.

Examples of the acetate-based solvent include propylene glycol methyl ether acetate (PGMEA), ethyl acetate, methyl 3-methoxypropionate, ethyl 3-ethoxypropionate, ethyllactate (EL), butyllactate (n-butylactate), 2-hydroxyethyl propionate, 2-hydroxy-2-methylethyl propionate, ethoxyethyl acetate, hydroxyethyl acetate, 2-hydroxy-3-methylbutanoic acidmethyl, 3-methoxymethyl propionate, 3-methoxyethyl propionate, 3-ethoxyethyl propionate, 3-ethoxymethyl propionate, methyl pyruvate, ethyl pyruvate, ethyl acetate, butyl acetate, methyl 2-hydroxyisobutyrate, n-butyl acetate, 1-methoxy-2-propyl acetate, methoxyethoxy propionate, ethoxyethoxypropionate, and/or a (e.g., any suitable) mixture thereof, but the present disclosure is not limited thereto.

A boiling point of the organic solvent including the ketone-based solvent may be about 100° C. to about 160° C.

When the boiling point is within the above range, a substantially uniform film can be formed due to appropriate or suitable volatility during coating, and surface unevenness such as pin holes caused by evaporation of residual organic solvent after a drying or soft baking process can be minimized or reduced.

The organic solvent including the ketone-based solvent may be included in an amount of about 70 wt % to about 99.5 wt % based on 100 wt % of the semiconductor photoresist composition.

The organometallic compound may be included in an amount of about 0.5 wt % to about 30 wt % based on 100 wt % of the semiconductor photoresist composition.

The organic acid compound may be p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but the present disclosure is not limited thereto.

The organic acid compound may be included in an amount of about 0.01 to about 20 wt % based on 100 wt % of the semiconductor photoresist composition.

For example, the organic acid compound may be included in an amount of about 0.01 to about 10 wt %, about 0.02 to about 10 wt %, about 0.03 to about 10 wt %, or about 0.05 to about 10 wt % based on 100 wt % of the semiconductor photoresist composition.

According to some example embodiments, the semiconductor photoresist composition can improve the sensitivity of a photoresist by including the organometallic compound, the ketone-based solvent, and the organic acid compound in the above content (e.g., amount) ranges.

The organometallic compound may be an organotin compound including at least one of an organooxy group or an organocarbonyloxy group.

For example, the organometallic compound may be represented by Chemical Formula 3.

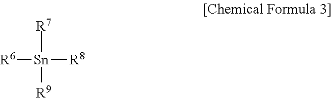

In Chemical Formula 3,

R⁶ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,

R⁷ to R⁹ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy and aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{h}C(NRⁱ)Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio and arylthiol group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), or a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and

at least one of R⁷ to R⁹ may be selected from among an alkoxy group and an aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylamido group and an dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted

C2 to C20 alkenyl group, a substituted or unsubstituted C2 to C20 alkynyl group, a substituted or unsubstituted C6 to C30 aryl group, and/or a (e.g., any suitable) combination thereof), an amidato group (—NR(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an amidinato group (—NR^{h}C(NRⁱ)Rⁱ, wherein R^{h}, Rⁱ, and Rⁱ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), an alkylthio group and an arylthiol group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

In one or more embodiments, at least one of R⁷ to R⁹ may be selected from among an alkoxy group and an aryloxy group (—OR^{b}, wherein R^{a} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof), and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof).

In one or more embodiments, the compound represented by Chemical Formula 3 includes-OR^{b} or —OC(═O)R^{e} as a ligand, so that a pattern formed using the semiconductor photoresist composition including this compound can exhibit excellent or suitable limit resolution.

Additionally, the ligand of —OR^{b} or —OC(═O)R^{c} may influence or determine the solubility of the compound represented by Chemical Formula 3 in a solvent.

In one or more embodiments, R⁶ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, and/or a (e.g., any suitable) combination thereof,

R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and/or a (e.g., any suitable) combination thereof, and

R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and/or a (e.g., any suitable) combination thereof.

In one or more embodiments, R⁶ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, and/or a (e.g., any suitable) combination thereof,

R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, and/or a (e.g., any suitable) combination thereof, and

R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, and/or a (e.g., any suitable) combination thereof.

In one or more embodiments, the Sn-containing organometallic compound may be represented by Chemical Formula 4 or Chemical Formula 5.

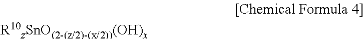

In Chemical Formula 4,

R¹⁰ may be a C1 to C31 hydrocarbyl group, 0<z≤2, and 0< (z+x)≤4;

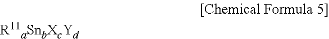

wherein, in Chemical Formula 5,

R¹¹ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, and/or a (e.g., any suitable) combination thereof,

X may be sulfur(S), selenium (Se), or tellurium (Te),

Y may be —OR^{m} or —OC(═O) Rⁿ,

R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof,

Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and/or a (e.g., any suitable) combination thereof, and

a, b, c, and d may each independently be an integer of 1 to 20.

In some example embodiments, the semiconductor photoresist composition may further include a resin in addition to the aforementioned organometallic compound, and ketone-based solvent.

The resin may be a phenolic resin including at least one aromatic moiety listed in (e.g., selected from among those in) Group 1.

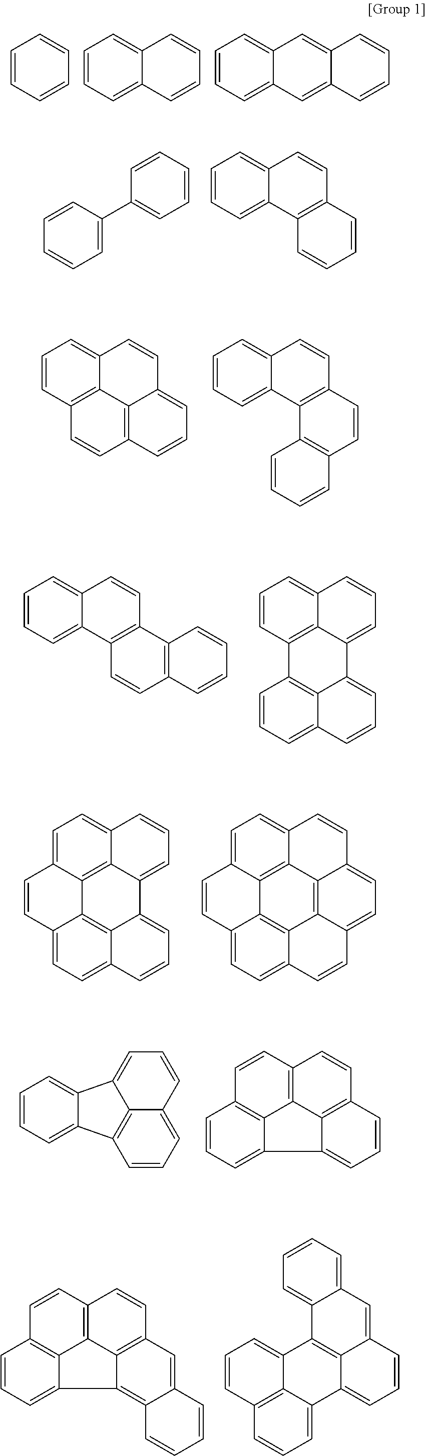

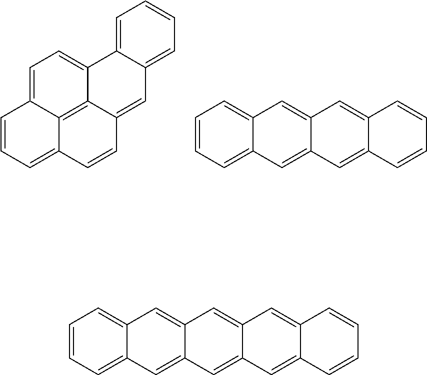

The resin may have a weight average molecular weight of about 500 to about 20,000.

The resin may be included in an amount of about 0.1 wt % to about 50 wt % based on a total amount of the semiconductor photoresist composition.

If (e.g., when) the resin is included within the above content (e.g., amount) range, the semiconductor photoresist composition can have excellent or suitable etching resistance and heat resistance.

In one or more embodiments, the semiconductor photoresist composition may be composed of the aforementioned organometallic compound, organic solvent including the ketone-based solvent, organic acid compound, and resin.

However, embodiments of the present disclosure are not limited thereto and the semiconductor photoresist composition according to one or more embodiments may further include additives. Examples of the additives may include a surfactant, a crosslinking agent, a leveling agent, a quencher, and/or a (e.g., any suitable) combination thereof.

The surfactant may include, for example, an alkyl benzene sulfonate salt, an alkyl pyridinium salt, polyethylene glycol, a quaternary ammonium salt, and/or a (e.g., any suitable) combination thereof, but the present disclosure is not limited thereto.

The crosslinking agent may be for example a melamine-based crosslinking agent, a substituted urea-based crosslinking agent, an acryl-based crosslinking agent, an epoxy-based crosslinking agent, or a polymer-based crosslinking agent, but the present disclosure is not limited thereto. The crosslinking agent may have at least two crosslinking forming substituents, for example, the crosslinking agent may be a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis (glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The quencher may be diphenyl (p-tolyl)amine, methyl diphenyl amine, triphenyl amine, phenylenediamine, naphthylamine, diaminonaphthalene, and/or a (e.g., any suitable) combination thereof.

An amount of these other additives may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris (β-methoxyethoxy) silane; or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl]silane, and/or the like, but the present disclosure is not limited thereto.

The semiconductor photoresist composition may be formed into a pattern having a high aspect ratio without a collapse (e.g., a pattern that does not collapse). Accordingly, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, or about 5 nm to about 20 nm, the semiconductor photoresist composition may be used for a photoresist process using light in a wavelength range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some example embodiments may be used to realize extreme ultraviolet lithography using an EUV light source of a wavelength of about 13.5 nm.

According to some example embodiments, a method of forming patterns using the aforementioned semiconductor photoresist composition is provided. For example, the manufactured pattern may be a photoresist pattern.

The method of forming patterns according to some example embodiments includes forming an etching-objective layer on a substrate, coating the semiconductor photoresist composition on the etching-objective layer to form a photoresist layer, patterning the photoresist layer to form a photoresist pattern and etching the etching-objective layer using the photoresist pattern as an etching mask.

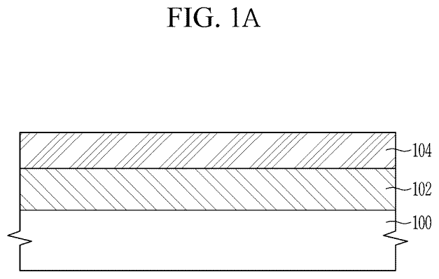

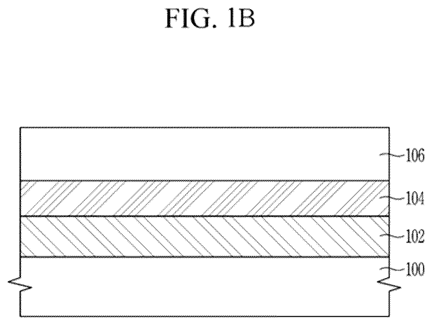

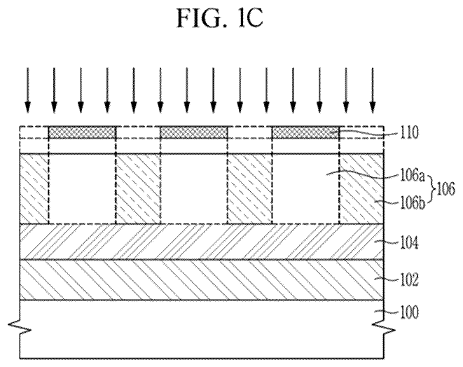

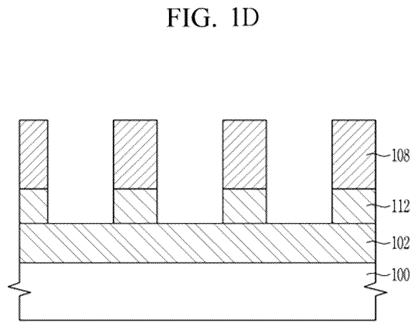

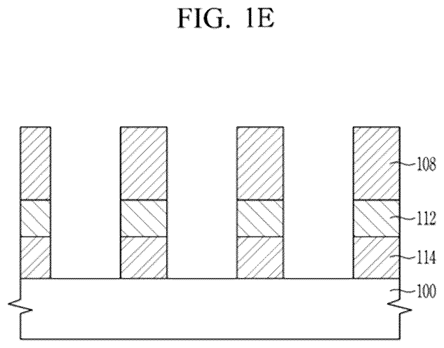

Hereinafter, a method of forming patterns using the semiconductor photoresist composition is described by referring to FIGS. 1A-1E. FIGS. 1A-1E are cross-sectional views for explaining a method of forming patterns using a semiconductor photoresist composition according to some example embodiments.

Referring to FIG. 1A, an object for etching is prepared. The object for etching may be a thin film 102 formed on a semiconductor substrate 100. Hereinafter, as an example, the object for etching is limited to the thin film 102. A surface of the thin film 102 is washed to remove impurities and/or the like remaining thereon. The thin film 102 may be for example a silicon nitride layer, a polysilicon layer, or a silicon oxide layer.

Subsequently, the resist underlayer composition for forming a resist underlayer 104 is spin-coated on the surface of the washed thin film 102. However, one or more embodiments are not limited thereto, and any suitable coating methods, for example, a spray coating, a dip coating, a knife edge coating, a printing method (for example, an inkjet printing and/or a screen printing), and/or the like may be used. In some embodiments, the coating process of the resist underlayer may not

be provided. Hereinafter, as an example, a process including the coating of the resist underlayer is described.

Then, the coated composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and unintended pattern formability of a photoresist line width if (e.g., when) a ray reflected from on the interface between the substrate 100 and the photoresist layer 106 or a hardmask between layers is scattered into an unintended photoresist region.

Referring to FIG. 1B, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In some embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist layer 106.

The semiconductor photoresist composition has already been illustrated in more detail and will not be illustrated again.

Subsequently, the substrate 100 having the photoresist layer 106 thereon is subjected to a first baking process. The first baking process may be performed at about 80° C. to about 120° C.

Referring to FIG. 1C, the photoresist layer 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as light having a wavelength such as an i-line (a wavelength of about 365 nm), a KrF excimer laser (a wavelength of about 248 nm), an ArF excimer laser (a wavelength of about 193 nm), and/or the like.

Light for the exposure according to some example embodiments may have a wavelength in a range of about 5 nm to about 150 nm or a high energy wavelength, for example, EUV (extreme ultraviolet; a wavelength of 13.5 nm), an E-Beam (an electron beam), and/or the like.

The exposed region 106b of the photoresist layer 106 has a different solubility from the unexposed region 106a of the photoresist layer 106 by forming a polymer through a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist layer 106 becomes indissoluble (e.g., easily indissoluble) by a developer due to the second baking process.

In FIG. 1D, the unexposed region 106a of the photoresist layer is dissolved and removed using the developer to form a photoresist pattern 108. For example, the unexposed region 106a of the photoresist layer is dissolved and removed by using an organic solvent such as 2-heptanone and/or the like to complete the photoresist pattern 108 corresponding to the negative tone image.

As described above, a developer used in a method of forming patterns according to some example embodiments may be an organic solvent. The organic solvent used in the method of forming patterns according to some example embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, and/or a (e.g., any suitable) combination thereof.

However, the photoresist pattern according to some example embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, and/or a (e.g., any suitable) combination thereof.

As described above, exposure to light having a high energy such as EUV (extreme ultraViolet; a wavelength of 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness (e.g., having a width) of about 5 nm to about 100 nm. For example, the photoresist pattern 108 may have a width of a thickness (e.g., having a width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

Also, the photoresist pattern 108 may have a pitch with a half-pitch of less than or equal to about 50 nm, for example, less than or equal to about 40 nm, less than or equal to about 30 nm, less than or equal to about 20 nm, or less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be, for example, CHF₃, CF₄, Cl₂, BCl₃s or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of about 5 nm to about 100 nm which is equal to or substantially equal to that of the photoresist pattern 108.

For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or less than or equal to about 20 nm, the same as or similar to the width of the photoresist pattern 108.

Hereinafter, the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

40.7 g of t-butylSnPhs and 300 g of propionic acid were added to a 250 mL two-necked round-bottom flask and heated under reflux for 24 hours.

Unreacted propionic acid was removed under reduced pressure to obtain a compound represented by Chemical Formula 6.

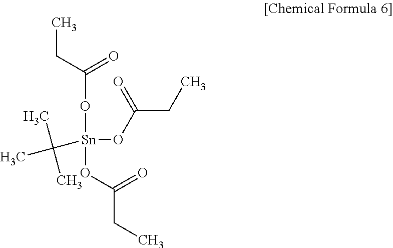 [SMILES: CCC(=O)[O][Sn]([O]C(=O)CC)([O]C(=O)CC)[C](C)(C)C]

### Synthesis Example 2

After adding 30 mL of anhydrous pentane to 10 g of t-AmylSnCl₃ and maintaining the temperature at 0° C., 7.4 g of diethyl amine and 6.1 g of ethanol were added thereto and then, stirred at room temperature for 1 hour. When the reaction was completed, the resultant was filtered, concentrated, and vacuum-dried, thereby obtaining a compound represented by Chemical Formula 7.

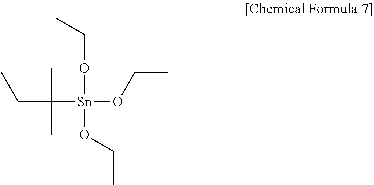

### Synthesis Example 3

10 g of dibutyltin dichloride was dissolved 30 mL of ether, 70 mL of a 1 M sodium hydroxide (NaOH) aqueous solution was added thereto and then, stirred for 1 hour. After the stirring, a solid produced therein was filtered, washed three times with 25 mL of deionized water, and dried at 100° C. under a reduced pressure to obtain an organometallic compound represented by Chemical Formula 8, which has a weight average molecular weight of 1,500.

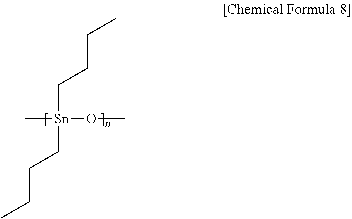

### Preparation of Semiconductor Photoresist Compositions

### Examples 1 to 13 and Comparative Examples 1 to 3

Each semiconductor photoresist composition of Examples 1 to 12 and Comparative Examples 1 to 4 was prepared by dissolving an organic acid compound (propionic acid, 0.05 wt %) and an organometallic compound (2.95 wt %) respectively represented by Chemical Formulas 6 to 8 according to Synthesis Examples 1 to 3 at a combined concentration of 3 wt % in each organic solvent S1 to S5 having a composition shown in Table 1 and then, filtering the obtained solution with a 0.1 μm PTFE (polytetrafluoroethylene) syringe filter.

TABLE 1

| | Organometallic compound | Organic solvent | |
|---|---|---|---|
| | (wt %) | (wt %) | |
| Comparative | Chemical Formula 6 (2.95) | S4 | (97.0) |
| Example 1 | | | |
| Comparative | Chemical Formula 6 (2.95) | S5 | (97.0) |
| Example 2 | | | |
| Example 1 | Chemical Formula 6 (2.95) | S1 | (97.0) |
| Example 2 | Chemical Formula 6 (2.95) | S2 | (97.0) |
| Example 3 | Chemical Formula 6 (2.95) | S3 | (97.0) |
| Example 4 | Chemical Formula 6 (2.95) | S3 + S4* | (97.0) |
| Comparative | Chemical Formula 7 (2.95) | S4 | (97.0) |
| Example 3 | | | |
| Example 5 | Chemical Formula 7 (2.95) | S1 | (97.0) |
| Example 6 | Chemical Formula 7 (2.95) | S2 | (97.0) |
| Example 7 | Chemical Formula 7 (2.95) | S3 | (97.0) |
| Example 8 | Chemical Formula 7 (2.95) | S3 + S4* | (97.0) |
| Comparative | Chemical Formula 8 (2.95) | S4 | (97.0) |
| Example 4 | | | |
| Example 9 | Chemical Formula 8 (2.95) | S1 | (97.0) |
| Example 10 | Chemical Formula 8 (2.95) | S2 | (97.0) |
| Example 11 | Chemical Formula 8 (2.95) | S3 | (97.0) |
| Example 12 | Chemical Formula 8 (2.95) | S3 + S4* | (97.0) |

(S3:S4* mixing weight ratio = 70:30)
S1: 2-heptanone
S2: cyclohexanone
S3: 2-pentanone
S4: propylene glycol methyl ether acetate (PGMEA)
S5: methyl iso butyl carbinol (MIBC)

### Evaluation 1: Evaluation of Sensitivity and Line Edge Roughness (LER)

Each of the photoresist compositions according to Examples and Comparative Examples was spin-coated for 30 seconds at 1500 rpm, respectively, on a 200 mm circular silicon wafer whose surface was deposited with HMDS, baked at 110° C. for 60 seconds (the baking was conducted after the application (post-apply bake, PAB)), and left at room temperature (23±2° C.) for 30 seconds.

Subsequently, a straight line array of 50 circular pads with a diameter of 500 μm was projected onto each wafer on which the composition for a photoresist was coated by using EUV light (Lawrence Berkeley National Laboratory Micro Exposure

Tool, MET). Pad exposure time was adjusted to ensure that the EUV light in an increased dose was applied to each pad.

Then, the resist and substrate were exposed to a temperature of 160° C. on a hot plate for 120 seconds, and then baked. The baked film was developed with a PGMEA solvent to form a negative tone image. Finally, the obtained film was baked again at 150° C. for 2 minutes on the hot plate, thereby completing the process.

Resist line widths according to an exposure dose (energy) changes were measured by using critical dimension (CD)—SEM. A difference in resist line widths formed under different exposure doses were used to confirm appropriate or suitable sensitivity according to the expose doses to evaluate sensitivity and LER according to the following criteria, and the results are shown in Table 2.

### [Sensitivity Evaluation Criteria]

A: less than 50 mJ/cm²
B: greater than or equal to 50 mJ/cm²

### [LER Evaluation Criteria]

o: less than or equal to 2 nm
Δ: greater than 2 nm and less than or equal to 5 nm
X: greater than 5 nm

### Evaluation 2: Evaluation of Delay Characteristics

Each of the photoresist compositions according to the examples and the comparative examples was spin-coated on a 200 mm circular silicon wafer, of which the surface was deposited with HMDS, at 1500 rpm for 30 seconds, and then, baked (post-apply baked, PAB) at 100° C. to 120° C. for 60 seconds and allowed to stand at room temperature for 10 minutes (process delay time).

Subsequently, a linear array of 50 circular pads with a diameter of 500 μm was projected onto the wafer coated with the photoresist composition by using EUV light (Lawrence Berkeley National Laboratory Micro Exposure Tool, MET). Pad exposure time was adjusted so that an increased EUV dose was applied to each pad.

Subsequently, the resist and the substrate were exposed at 180° C. for 120 seconds on a hot plate and then, baked. The baked film was developed with a PGMEA solvent to form negative tone image and finally baked at 150° C. for 2 minutes on the hot plate, thereby completing a process.

The resist line widths formed by exposure with the same dose (energy) were measured by using CD-SEM. Each resist pattern respectively formed according to process delay time (10 minutes, 20 minutes, 30 minutes, 40 minutes, 50 minutes, 60 minutes) was measured with respect to line widths (CD), which were used to calculate delay characteristics according to Equation 1, and the results are shown in Table 2.

$$Delay characteristics = \{ Maximum CD value among the CD values of each pattern \\ formed a 10 - minutes intervals for 60 minutes after PAB / \\ CD value of the pattern formed without leaving \} * 100 \qquad [ Equation 1 ]$$

### [Evaluation Criteria]

⊚: ΔCD greater than 2% and less than or equal to 7%
o: ΔCD greater than 7% and less than or equal to 15%
X: ΔCD greater than 15%

TABLE 2

| | Sensitivity | LER | Delay characteristics |
|---|---|---|---|
| Comparative Example 1 | B | ◯ | Δ |
| Comparative Example 2 | B | ◯ | Δ |
| Example 1 | A | ◯ | ⊚ |
| Example 2 | B | ◯ | ◯ |
| Example 3 | A | ◯ | ⊚ |
| Example 4 | A | ◯ | ⊚ |
| Comparative Example 3 | B | Δ | Δ |
| Example 5 | B | ◯ | ◯ |
| Example 6 | B | ◯ | ◯ |
| Example 7 | B | ◯ | ⊚ |
| Example 8 | B | ◯ | ⊚ |
| Comparative Example 4 | B | ◯ | Δ |
| Example 9 | B | ◯ | ◯ |
| Example 10 | B | ◯ | ◯ |
| Example 11 | B | ◯ | ◯ |
| Example 12 | B | ◯ | ⊚ |

From the results in Table 2, the patterns formed using the semiconductor photoresist compositions according to Examples have enhanced (e.g., excellent or suitable) sensitivity and/or delay characteristics compared to those formed using the semiconductor photoresist compositions according to Comparative Examples.

For example, it should be evident that the patterns formed using the semiconductor photoresist compositions according to Examples exhibit enhanced sensitivity and delay characteristics compared to those formed using the semiconductor photoresist compositions according to Comparative Examples. Specifically, the photoresist compositions in Examples demonstrate superior sensitivity, as indicated by lower exposure doses required to achieve the desired patterning. Additionally, the line edge roughness (LER) of the patterns formed using these compositions is consistently lower, ensuring higher precision and quality in the semiconductor devices. The delay characteristics, evaluated based on the change in critical dimension (CD) values over time, show that the photoresist compositions in

Examples maintain their performance stability even after extended process delays. This stability is crucial for practical applications in semiconductor manufacturing, where process delays are common. Overall, the semiconductor photoresist compositions according to Examples provide a significant improvement in both sensitivity and delay characteristics, making them highly suitable for advanced semiconductor device fabrication.

In other words, Examples 1 to 12 detail the preparation and evaluation of semiconductor photoresist compositions using various organometallic compounds and organic solvents. The compositions were tested for sensitivity, line edge roughness (LER), and delay characteristics. Examples 1 to 4 utilized Chemical Formula 6 with different solvents (S1 to S4) and a mixture of S3 and S4. These compositions showed excellent sensitivity and LER, with some demonstrating superior delay characteristics. Examples 5 to 8 utilized Chemical Formula 7 with different solvents (S1 to S4) and a mixture of S3 and S4. These compositions generally showed good sensitivity and LER, with some exhibiting improved delay characteristics. Examples 9 to 12 utilized

Chemical Formula 8 with different solvents (S1 to S4) and a mixture of S3 and S4. These compositions consistently showed good sensitivity and LER, with some demonstrating enhanced delay characteristics. Comparative Examples 1 to 4 used the same organometallic compounds as the Examples but with different solvents (S4 and S5). The comparative compositions generally showed lower sensitivity and less favorable delay characteristics compared to the Examples.

It will be further understood that if (e.g., when) the terms “comprises,” “including,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof. For example, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “combination thereof” refers to a mixture, a laminate, a composite, a copolymer, an alloy, a blend, a reaction product, and/or the like of the constituents.

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A device of forming patterns, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Hereinbefore, the certain embodiments have been described and illustrated, however, it is apparent to a person with ordinary skill in the art that the present disclosure is not limited to one or more embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims of the present disclosure, and equivalents thereof.

Reference Numerals

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
an organometallic compound;
an organic solvent comprising a ketone-based solvent; and
an organic acid compound.

2. The semiconductor photoresist composition as claimed in claim 1, wherein
the ketone-based solvent is represented by Chemical Formula 1 or Chemical Formula 2: 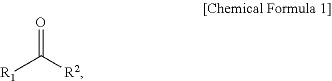
wherein, in Chemical Formula 1,
R¹ and R² are each independently a substituted or unsubstituted C1 to C10 alkyl group; 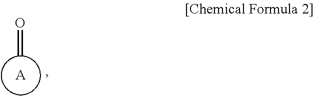
and
wherein, in Chemical Formula 2,
ring A is a substituted or unsubstituted C3 to C10 cycloalkyl group.

3. The semiconductor photoresist composition as claimed in claim 2, wherein
the ketone-based solvent represented by Chemical Formula 1 is represented by any one selected from among Chemical Formula 1-1 to Chemical Formula 1-4: 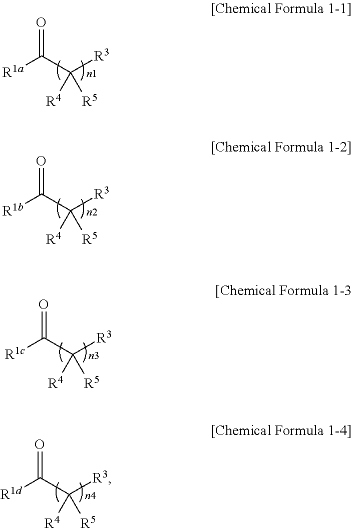
and
wherein, in Chemical Formula 1-1 to Chemical Formula 1-4,
R^{1a} is a substituted or unsubstituted methyl group,
R^{1b} is a substituted or unsubstituted ethyl group,
R^{1c} is a substituted or unsubstituted propyl group,
R^{1d} is a substituted or unsubstituted butyl group,
R³ is a substituted or unsubstituted methyl group,
n1 is an integer of 1 to 7,
n2 is an integer of 1 to 6,
n3 is an integer of 1 to 5,
n4 is an integer of 1 to 4, and
R⁴ and R⁵ are each independently hydrogen, halogen, a substituted or unsubstituted C1 to C5 alkyl group, a substituted or unsubstituted C3 to C10 cycloalkyl group, a substituted or unsubstituted C6 to C12 aryl group, or a combination thereof.

4. The semiconductor photoresist composition as claimed in claim 3, wherein
1 n1 is an integer of 1 to 5,
n2 is an integer of 1 to 4,
n3 is an integer of 1 to 3, and
n4 is 1 or 2.

5. The semiconductor photoresist composition as claimed in claim 3, wherein
the ketone-based solvent represented by Chemical Formula 1 is represented by any one of Chemical Formula 1-1 to Chemical Formula 1-3,
n1 is an integer of 1 to 3,
n2 is 1 to 2, and
n3 is 1.

6. The semiconductor photoresist composition as claimed in claim 3, wherein
the ketone-based solvent represented by Chemical Formula 1 is represented by Chemical Formula 1-1 or Chemical Formula 1-2,
n1 is 1 to 2, and
n2 is 1.

7. The semiconductor photoresist composition as claimed in claim 1, wherein
the organic solvent comprising the ketone-based solvent further comprises an acetate-based solvent.

8. The semiconductor photoresist composition as claimed in claim 7, wherein
a weight ratio between the ketone-based solvent and the acetate-based solvent is about 99:1 to about 50:50.

9. The semiconductor photoresist composition as claimed in claim 1, wherein
a boiling point of the organic solvent comprising the ketone-based solvent is about 100 to about 160° C.

10. The semiconductor photoresist composition as claimed in claim 1, wherein
the organic solvent comprising the ketone-based solvent is about 70 wt % to about 99.5 wt % in amount based on 100 wt % of the semiconductor photoresist composition.

11. The semiconductor photoresist composition as claimed in claim 1, wherein
the organometallic compound is about 0.5 wt % to about 30 wt % in amount based on 100 wt % of the semiconductor photoresist composition.

12. The semiconductor photoresist composition as claimed in claim 1, wherein
the organic acid compound is selected from among p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and a combination thereof.

13. The semiconductor photoresist composition as claimed in claim 1, wherein
the semiconductor photoresist composition further comprises an additive selected from among a surfactant, a crosslinking agent, a leveling agent, a quencher, and a combination thereof.

14. The semiconductor photoresist composition as claimed in claim 1, wherein
the organometallic compound is an organotin compound comprising an organooxy group and/or an organocarbonyloxy group.

15. The semiconductor photoresist composition as claimed in claim 1, wherein
the organometallic compound is represented by Chemical Formula 3: 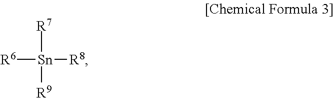
wherein, in Chemical Formula 3,
R⁶ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R⁷ to R⁹ are each independently a substituted or unsubstituted C3 to C20 cycloalkyl group; a substituted or unsubstituted C2 to C20 alkenyl group; a substituted or unsubstituted C2 to C20 alkynyl group; a substituted or unsubstituted C6 to C30 aryl group; a substituted or unsubstituted C7 to C30 arylalkyl group; an alkoxy or aryloxy group represented by —OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; a carboxyl group represented by —O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylamido or dialkylamido group represented by —NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidato group represented by —NR(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an amidinato group represented by —NR^{h}C(NRⁱ)Rⁱ, wherein R^{h}, Rⁱ, and Rⁱ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; an alkylthio or arylthiol group represented by —SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; or a thiocarboxyl group represented by —S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof; and
at least one of R⁷ to R⁹ is the alkoxy or aryloxy represented by —OR^{b}; the carboxyl group represented by —O(CO)R^{c}; the alkylamido or dialkylamido group represented by —NR^{d}R^{e}; the amidato group represented by —NR^{f}(COR^{g}); the amidinato group represented by —NR^{h}C(NRⁱ)Rⁱ; the alkylthio or arylthiol group represented by —SR^{k}; or the thiocarboxyl group represented by —S(CO)R^{l}.

16. The semiconductor photoresist composition as claimed in claim 15, wherein
at least one of R⁷ to R⁹ is the alkoxy or aryloxy group represented by —OR^{b}, or the carboxyl group represented by —O(CO)R^{c}.

17. The semiconductor photoresist composition as claimed in claim 16, wherein
R⁶ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

18. The semiconductor photoresist composition as claimed in claim 1, wherein
the organometallic compound is represented by Chemical Formula 4 or Chemical Formula 5: 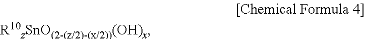
wherein, in Chemical Formula 4,
R¹⁰ is a C1 to C31 hydrocarbyl group, 0<z≤2, and 0< (z+x)≤4; 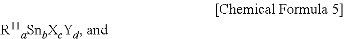
wherein, in Chemical Formula 5,
R¹¹ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur(S), selenium (Se), or tellurium (Te),
Y is —OR^{m} or —OC(═O)Rⁿ,
R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

19. A method comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer utilizing the photoresist pattern as an etching mask,
wherein the method is for forming patterns.

20. The method as claimed in claim 19, wherein the patterning of the photoresist layer comprises selectively exposing the photoresist layer to a light source selected from extreme ultraviolet, an electron beam, an i-line, a KrF excimer laser, and an ArF excimer laser.
